(19) United States
(12) Patent Application Publication
(10) Pub. No.: US 2026/0323882 A1
(43) Pub. Date: Oct. 15, 2026

(54) HEAT SINK STRUCTURE WITH ENCLOSURE AND GRAPHITE SHEET AND PRINTED CIRUIT BOARD ASSEMBLY INCLUDING THE SAME

(71) Applicant: HANWHA SOLUTIONS CORPORATION, Seoul (KR)

(72) Inventors: Zheng SHEN, Santa Clara, CA (US); Matthew MILLER, Santa Clara, CA (US)

(73) Assignee: HANWHA SOLUTIONS CORPORATION, Seoul (KR)

(21) Appl. No.: 19/175,058

(22) Filed: Apr. 10, 2025

(51) Int. Cl. H05K 7/20; H05K 1/02

(52) U.S. Cl. CPC H05K 7/20409; H05K 1/0203; H05K 7/20509; H05K 2201/066; H05K 2201/0753

(57) ABSTRACT

Disclosed are heat sink structures and printed circuit board assemblies including the same. A heat sink structure may include an enclosure having a first horizontal thermal conductivity, the enclosure having an upper surface including a first area at a first height, a second area at a second height different from the first height, and a third area connecting the first area to the second area with inclination, and a graphite sheet on the enclosure, the graphite sheet having a second horizontal thermal conductivity greater than the first horizontal thermal conductivity of the enclosure, the graphite sheet conformally covering the first area, the third area, and at least a portion of the second area of the enclosure, the graphite sheet including at least one cutout.

### BACKGROUND

### 1. Field

Example embodiments of the present disclosure relate to heat sink assemblies, printed circuit board assemblies (PCBA) including the same, and/or methods of manufacturing the same.

### 2. Description of the Related Art

Generally, a printed circuit assembly (PCBA) includes a multi-part assembly composed of a printed circuit board (PCB), on which heat sources (e.g., an electronic components) are mounted, a heat spreader under the PCB and attached to the PCB with a thermal pad therebetween, an enclosure (or alternatively referred to as a “heat sink”) under the heat spreader with a thermal grease therebetween. The heat spreader may include metal such as aluminum. According to such PCBA, heat generated by the heat sources mounted on the PCB can be transferred to the outside via multiple thermal interface materials, thereby reducing thermal resistance of an electronic component(s) mounted on the PCB. However, stacking multiple thermal interface materials increases manufacturing costs and/or assembly time. Further, heat dissipation of a PCBA including a metal-based heat spreader may not be sufficiently effective in certain applications and/or may not be desirable due to its relatively thick thickness.

A graphite sheet is known to have a thermal conductivity on a horizontal plane significantly higher than a thermal conductivity in a through plane (e.g., a vertical plane). Thus, a graphite sheet may be added on the enclosure to replace a metal-based heat spreader. When a cold drawing process is used to shape the graphite sheet to mold around a raised surface of a heat sink thereunder, however, the extent that a portion of the graphite sheet can be raised may be limited to about 1/2 the thickness of the graphite sheet. Thus, shaping the graphite sheet using the cold drawing process may not be a viable process in certain situations.

### SUMMARY

Some example embodiments of the present disclosure relate to heat sink structures.

Some example embodiments of the present disclosure relate to printed circuit board assemblies (PCBAs).

According to an example embodiment of the present disclosure, a heat sink structure includes an enclosure having a first horizontal thermal conductivity, the enclosure having an upper surface including a first area at a first height, a second area at a second height different from the first height, and a third area connecting the first area to the second area with inclination, and a graphite sheet on the enclosure, the graphite sheet having a second horizontal thermal conductivity greater than the first horizontal thermal conductivity of the enclosure, the graphite sheet conformally covering the first area, the third area, and at least a portion of the second area of the enclosure, the graphite sheet including at least one cutout.

The cutout may have one of an X shape, an M shape, or a U shape.

The cutout may include a first cutout area on the first area of the upper surface of the enclosure, a second cutout area on the second area of the upper surface of the enclosure, and a third cutout area on the third area of the upper surface of the enclosure, the third cutout area connecting the first cutout area to the second cutout area.

The second cutout area may have a length between 0.5 mm and 1 mm in an extension direction of the cutout.

The graphite sheet may have an area of at least two times an area of the first area of the enclosure.

An angle of the inclination of the third area of the enclosure may be 135 degrees or more based on the second area of the enclosure.

The heat sink structure of claim 1 may further include an adhesive layer between the enclosure and the graphite sheet.

The graphite sheet may have a height difference of 0.2 mm or more between a lowest point and a highest point thereof.

The enclosure may include a plastic material.

At least one of the first area or the second area of the enclosure may be a flat surface.

A printed circuit board assembly (PCBA) includes a heat sink structure including an enclosure and a graphite sheet thereon, the enclosure having a first horizontal thermal conductivity, the enclosure having an upper surface including a first area at a first height, a second area at a second height different from the first height, a third area connecting the first area to the second area with inclination, and the graphite sheet having a second horizontal thermal conductivity greater than the first horizontal thermal conductivity of the enclosure, the graphite sheet conformally covering the first area, the third area, and at least a portion of the second area of the enclosure, the graphite sheet including at least one cutout, a printed circuit board (PCB) on the graphite sheet, the PCB configured to mount thereon a heat generating component, and a thermal pad interposed between the graphite sheet and the PCB.

The first area of the enclosure may be under and in alignment with an area of the PCB, on which the heat generating component is to be mounted.

The cutout may have one of an X shape, an M shape, or a U shape.

The cutout may include a first cutout area on the first area of the upper surface of the enclosure, a second cutout area on the second area of the upper surface of the enclosure, and a third cutout area on the third area of the upper surface of the enclosure, the third cutout area connecting the first cutout area to the second cutout area.

The second cutout area may have a length between 0.5 mm and 1 mm in an extension direction of the cutout.

An angle of the inclination of the third area of the enclosure may be 135 degrees or more based on the second area of the enclosure.

The PCBA may further include an adhesive layer between the enclosure and the graphite sheet.

The thermal pad may include an insulating material layer and an elastomer material layer attached thereto.

The graphite sheet may have a height difference of 0.2 mm or more between a lowest point and a highest point thereof.

The PCBA may further include a potting material filling a space between the PCB and the graphite sheet around the first area of the enclosure.

### BRIEF DESCRIPTION OF THE DRAWINGS

Example embodiments will be more clearly understood from the following detailed description taken in conjunction with the accompanying drawings in which:

FIG. 1 is a perspective view of a heat sink structure according to an example embodiment;

FIG. 2 is an enlarged perspective view of a portion of the heat sink structure including an X shape cutout, according to an example embodiment;

FIG. 3 is a perspective cross-sectional view of the heat sink structure taken along line III-III′ of FIG. 2;

FIG. 4 is a cross-sectional view of the heat sink structure taken along line IV-IV′ of FIG. 2, according one example embodiment;

FIG. 5 is a cross-sectional view of the heat sink structure taken along line IV-IV′ of FIG. 2, according to another example embodiment;

FIG. 6 is an enlarged perspective view of a portion of the heat sink structure including a U shape cutout, according to an example embodiment;

FIG. 7A is a cross-sectional view of the heat sink structure including a U shape cutout taken along line VIIA-VIIA′ of FIG. 6;

FIG. 7B is a cross-sectional view of the heat sink structure including a U shape cutout taken along line VIIB-VIIB′ of FIG. 6;

FIG. 8 is an enlarged perspective view of a portion of the heat sink structure including a U shape cutout, according to another example embodiment

FIG. 9 is an enlarged perspective view of the heat sink structure including an M shape cutout, according to an example embodiment;

FIG. 10 is a cross-sectional view of the heat sink structure taken along line IX-IX′ of FIG. 9;

FIG. 11 is a cross-sectional view of a printed circuit board assembly (PCBA), according to an example embodiment;

FIG. 12 is a plan view of a front side of a PCBA, according to an example embodiment; and

FIG. 13 is a plan view of a rear side of a PCBA, according to an example embodiment.

### DETAILED DESCRIPTION

Various example embodiments will be described more fully hereinafter with reference to the accompanying drawings, in which some example embodiments are shown. The present disclosure may, however, be embodied in many different forms and should not be construed as limited to the example embodiments set forth herein. Rather, these example embodiments are merely provided so that this disclosure will be thorough and complete, and will fully convey the scope of example embodiments to those skilled in the art. In the drawings, the sizes and relative sizes of the various layers and regions may have been exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present.

As used herein, the term “and/or” includes any and all combinations of one or more of the associated listed items. Expressions such as “one of,” “any one of,” and “at least one of,” when preceding a list of elements, modify the entire list of elements and do not modify the individual elements of the list. Thus, for example, both “at least one of A, B, or C” and “A, B, and C” means either A, B, C or any combination thereof.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Thus, the regions illustrated in the figures are schematic in nature and their shapes are not intended to illustrate the actual shape of a region of a device and are not intended to limit the scope of example embodiments.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

Hereinafter, some example embodiments of the inventive concepts will be described in detail with reference to the accompanying drawings. Like components are denoted by like reference numerals throughout the specification, and repeated descriptions thereof are omitted.

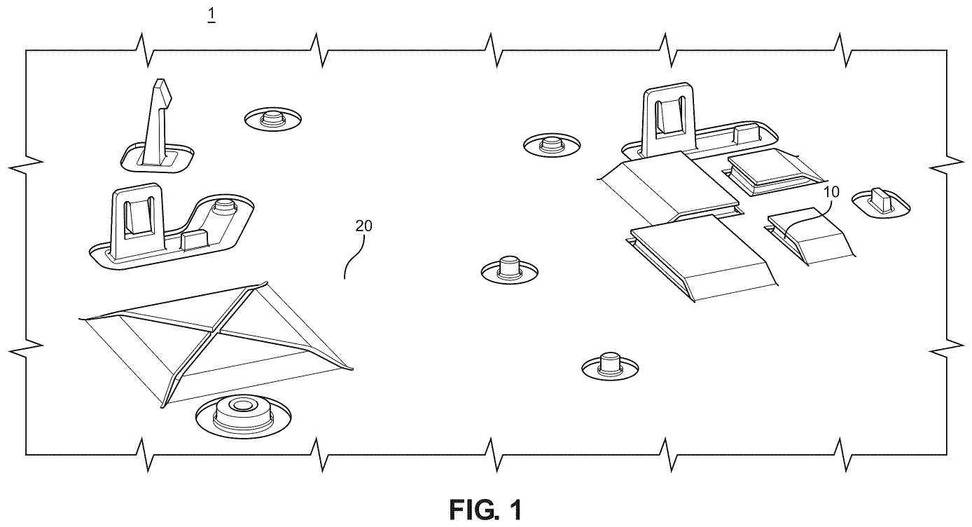

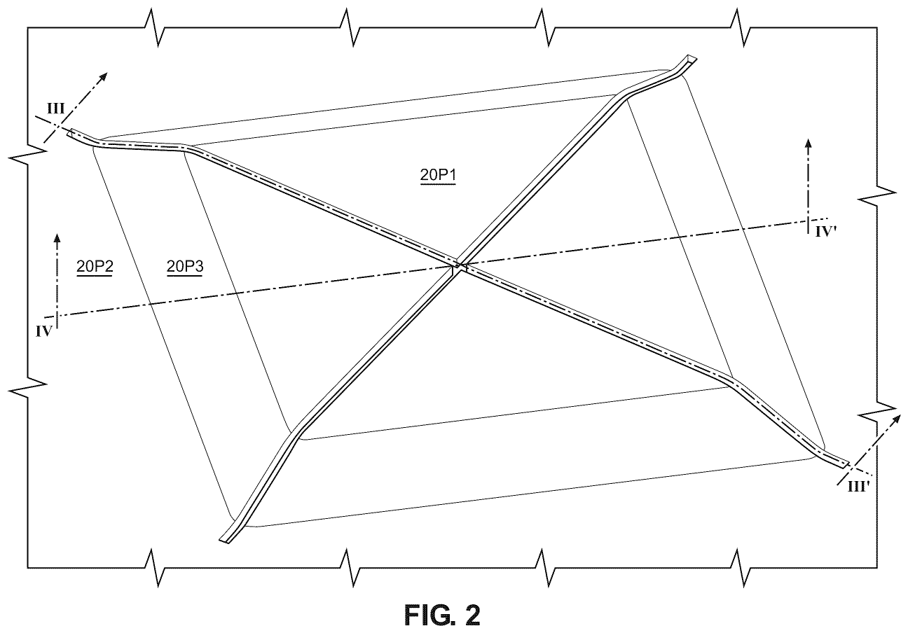

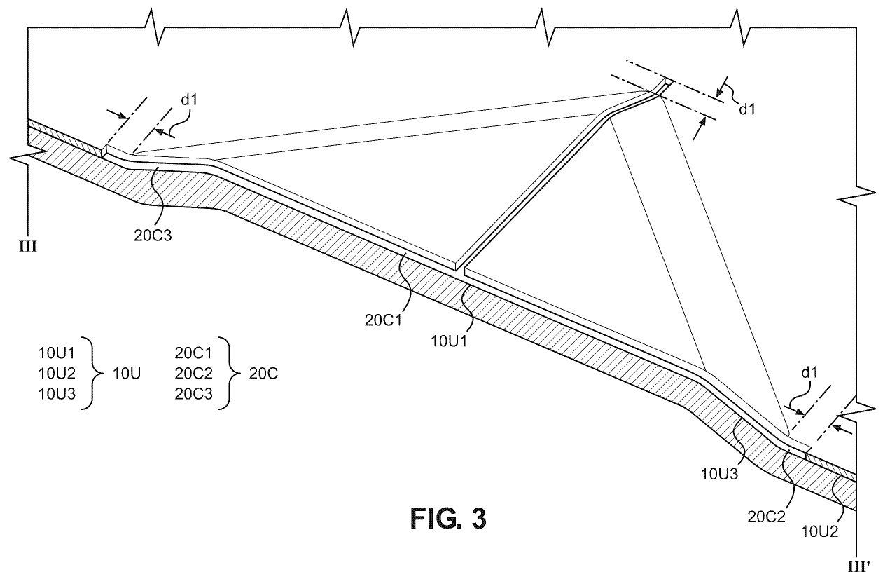

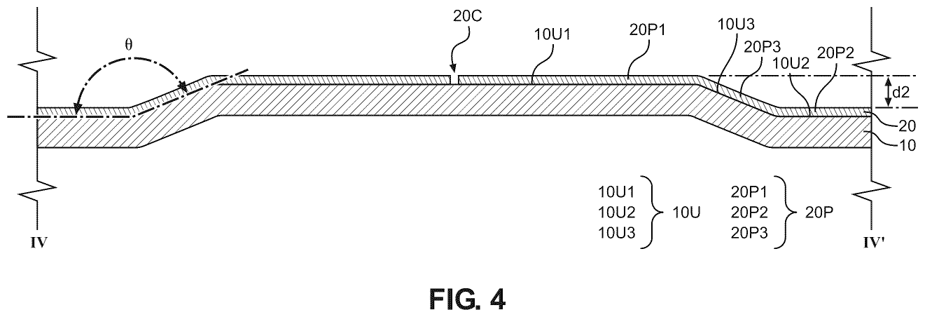

FIG. 1 is a perspective view of a heat sink structure according to an example embodiment. FIG. 2 is an enlarged perspective view of a portion of the heat sink structure including an X shape cutout, according to an example embodiment. FIG. 3 is a perspective cross-sectional view of the heat sink structure taken along line III-III′ of FIG. 2. FIG. 4 is a cross-sectional view of the heat sink structure taken along line IV-IV′ of FIG. 2, according to one example embodiment.

Referring to FIG. 1 in conjunction with FIGS. 2-4, a heat sink structure 1 may include an enclosure 10 and a graphite sheet 20 attached thereon. The enclosure 10 may have at least one raised area, which corresponds to a portion of at least one heat source (e.g., at least one electronic component) when the enclosure 10 is applied to a printed circuit board assembly (PCBA) having the at least one heat source mounted thereon. The enclosure 10 may have a first horizontal thermal conductivity. The enclosure 10 may include a plastic material. Depending on example embodiments, the enclosure 10 may be interchangeably referred to as a base, a heat sink, or a plastic enclosure.

The graphite sheet 20 may conformally cover the one or more raised areas of the enclosure 10. In this example embodiment, the graphite sheet 20 is provided as a single sheet conformally covering an entire surface of the enclosure 10. According to some example embodiments, however, the graphite sheet 20 may be provided as one or more graphite sheet patterns, which is provided locally to correspond to the one or more raised areas of the enclosure 10, respectively. Each of the one or more graphite sheet patterns may have at least two times an area of a corresponding one of the one or more raised areas of the enclosure 10 to provide efficient heat dissipation. The graphite sheet 20 may have a second horizontal thermal conductivity substantially greater that the first horizontal thermal conductivity of the enclosure 10. Thus, the graphite sheet 20 may have an area greater than a corresponding one of the one or more raised areas of the enclosure 10 in a plan view, thereby facilitating heat spreading.

The graphite sheet 20 may refer to a stack of thin graphite layers. The graphite sheet 20 may have a thermal conductivity in a horizontal plane (e.g., x-y plane) significantly higher than a thermal conductivity in a through plane (e.g. z plane), and thus may quickly spread heat throughout the entire surface of the graphite sheet 20. Ideally, the x-y plane thermal conductivity of graphite sheet 20 may be equal to or greater than about 20 times the z plane thermal conductivity of the graphite sheet 20 and/or the thermal conductivity of the enclosure 10. Accordingly, a hot spot (e.g., an areas at which the heat is relatively highly concentrated) may be reduced or prevented from occurring on the enclosure 10. In some example embodiments, the graphite sheet 20 may be NeoGraf eGRAF® SPREADERSHIELD™ SS500 Graphite, which has an x-y plane conductivity of about 500 W/m-K and a z-plane conductivity of about 2.8 W/m-K and may have a thickness of about 0.4 mm.

The graphite sheet 20 may include one or more raised portions each including a cutout. Referring to FIG. 1, the graphite sheet 20 includes one X shape cutout and four U shape cutouts on five raised portion thereof, respectively. However, the number of cutouts and/or shapes of cutouts are not limited thereto. According to some example embodiments, the graphite sheet 20 may include one or more cutout of an M shape.

FIG. 2 is an enlarged perspective view of a portion of the heat sink structure 1 including an X-shape cutout. FIG. 3 is a perspective cross-sectional view of the heat sink structure 1 taken along line III-III′ of FIG. 2. Referring to FIGS. 2 and 3, an upper surface 10U of the enclosure 10 may include a first area 10U1 at a first height, a second area 10U2 at a second height lower than the first height, and a third area 10U3 connecting the first area to the second area with inclination. According to some example embodiments, at least one of the first area or the second area of the enclosure may be a flat surface. In such case, the first area may be referred to as a raised flat surface and the second area may be referred to as a lower flat surface.

The graphite sheet 20 may include a first portion 20P1 on the first area 10U1 of the upper surface 10U of the enclosure 10, a second portion 20P2 on the second area 10U2 of the upper surface 10U of the enclosure 10, and a third portion 20P3 on the third area 10U3 of the upper surface 10U of the enclosure 10.

Referring to FIG. 3, the graphite sheet 20 may include a cutout 20C having an X shape (hereinafter, referred to as an X shape cutout). The X shape cutout 20C may include a first cutout area 20C1 on the first area 10U1 of the upper surface 10U of the enclosure 10, a second cutout area 20C2 on the second area 10U2 of the upper surface 10U of the enclosure 10, and a third cutout area 20C3 on the third area 10U3 of the upper surface 10U of the enclosure 10 and connecting (e.g., fluidly connecting) the first cutout area 20C1 to the second cutout area 20C2. The term “cutout area” may be interchangeably referred to as “cutout potion,” “cutout section,” or “cutout region.”

The cutout 20C may extend beyond the first area 10U1 of the upper surface 10U of the enclosure 10 to allow for stress relief. The cutout 20C may further extend beyond the third area 10U3 of the upper surface 10U of the enclosure 10. Accordingly, air gaps and graphite sheet wrinkles may be reduced or eliminated while attaching the graphite sheet 20 to the enclosure 10. If the cutout 20C does not extend beyond the first area 10U1 of the upper surface of the enclosure 10 (e.g., is equal to or less than the first area U1 of the enclosure 10) in a plan view, the graphite sheet 20 may be damaged when stamped to have a conformal shape according to the profile of the enclosure 10.

FIG. 4 is a cross-sectional view of the heat sink structure taken along line IV-IV′ of FIG. 2, according one example embodiment. Referring to FIG. 4, an angle θ of inclination of the third area 10U3 of the upper surface 10U of the enclosure 10 may be about 135 degrees or more based on the second area 10U2 of the upper surface 10U of the enclosure 10. Although there is no limitation as to a height, a depth and/or a width of the cutout 20C as long as the cutout 20C extends beyond the first area 10U1 of the upper surface 10U of the enclosure 10, when the angle θ of inclination of the third area 10U3 of the upper surface 10U of the enclosure 10 is steeper than a certain value, delamination of the graphite sheet 20 may occur. The angle θ of inclination may be interchangeably referred to as an approach angle θ.

From a standpoint of the X shape cutout 20C, an angle θ of inclination of the third cutout area 20C3 may be about 135 degrees or more based on the second cutout area 20C2. The X shape cutout 20C includes four third cutout areas 20C3 on four sides, respectively.

According to this example embodiment, it may be possible to implement the graphite sheet 20 having a distance or a height difference d2 between the highest point and the lowest point thereof to be about 0.2 mm or more.

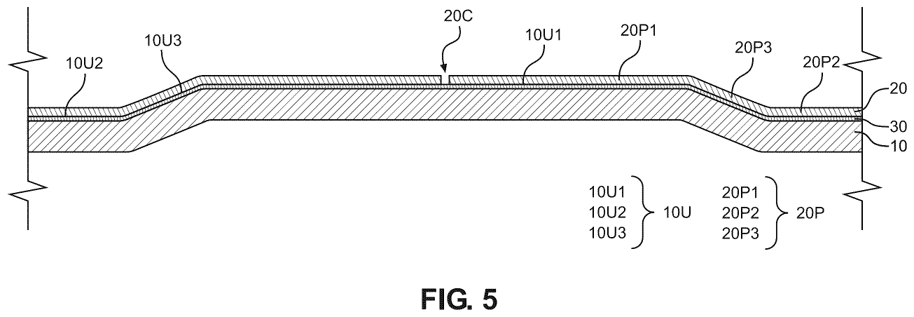

FIG. 5 is a cross-sectional view of the heat sink structure taken along line IV-IV′ of FIG. 2, according to another example embodiment. As illustrated, the heat sink structure 1 may further include an adhesive layer 30 between the enclosure 10 and the graphite sheet 20 to facilitate attachment therebetween.

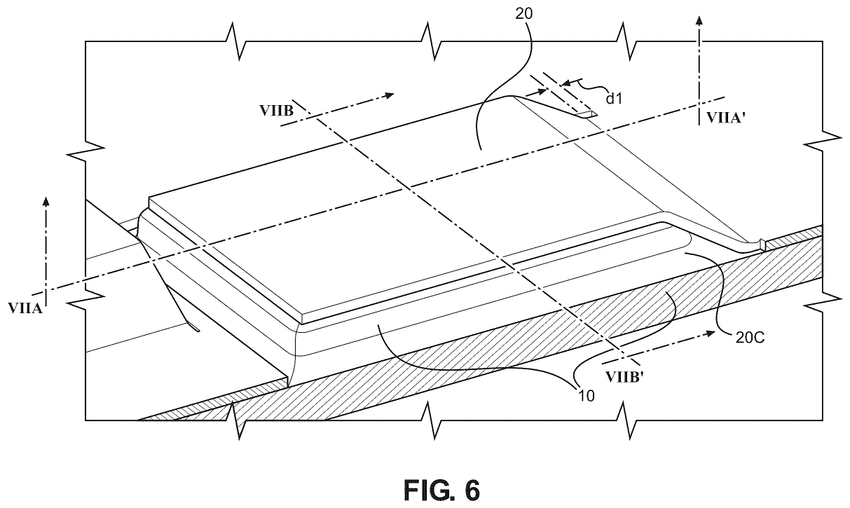

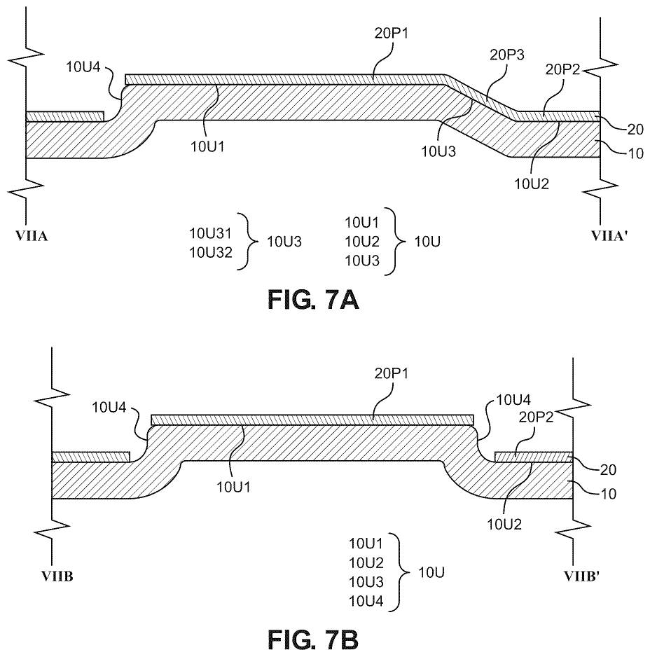

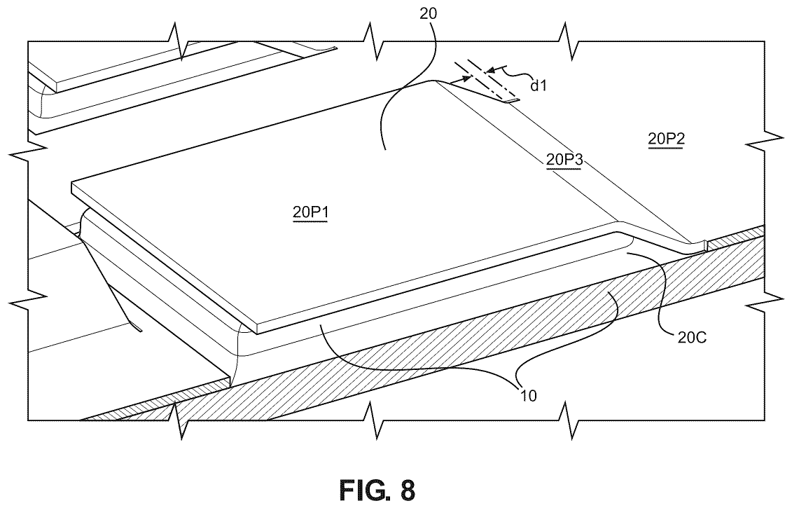

FIG. 6 is an enlarged perspective view of a portion of the heat sink structure including a U shape cutout, according to an example embodiment. FIG. 7A is a cross-sectional view of the heat sink structure taken along line VIIA-VIIA′ of FIG. 6. FIG. 7B is a cross-sectional view of the heat sink structure taken along line VIIB-VIIB′ of FIG. 6. FIG. 8 is an enlarged perspective view of a portion of the heat sink structure including a U shape cutout, according to another example embodiment. In FIGS. 6 and 8, the same reference numerals as in FIGS. 1-5 denote the same members, respectively. Thus, repeated descriptions thereof are omitted.

Referring to FIG. 7A, the upper surface 10U of the enclosure 10 includes four areas including a first area 10U1 at a first height, a second area 10U2 at a second height lower than the first height, a third area 10U3 connecting the first area 10U1 to the second area 10U2 on a first side of the first area 10U1 with inclination, and a fourth area 10U4 connecting the first area 10U1 to the second area 10U2 on a second side of the first area 10U1 opposite to the first side of the first area 10U1. The inclination of the fourth area 10U4 on the second side of the first area 10U1 may be steeper than the inclination of the third area 10U3 on the first side of the first area 10U1. In some example embodiments, the fourth area 10U4 may be rounded.

The graphite sheet 20 may include a first portion 20P1 on the first area 10U1 of the upper surface 10U of the enclosure 10, a second portion 20P2 on the second area 10U2 of the upper surface 10U of the enclosure 10, and a third portion 20P3 on the third area 10U3 of the upper surface 10U of the enclosure 10. In a plan view, the fourth area 10U4 of the upper surface 10U of the enclosure 10 may not be covered by the graphite sheet 20. In other words, in a plan view, the first portion 20P1 of the graphite sheet 20 may not overlap but may be adjacent to the fourth area 10U4 of the upper surface 10U of the enclosure 10.

Referring to FIG. 7B, in a cross-sectional view taken along line VIIB-VIIB′, the fourth area 10U4 in FIG. 7A may extend to surround three sides (e.g., one side in a direction of line VIIA-VIIA′ as shown in FIG. 7A and two opposite sides of 20P1 in a direction of line VIIV-VIIB′ as shown in FIG. 7B) of the first portion 20P1 of the graphite sheet 20, in a plan view. In a plan view, the fourth area 10U4 of the upper surface 10U of the enclosure 10 may not be covered by the graphite sheet 20. In other words, in a plan view, the first portion 20P1 of the graphite sheet 20 may not overlap but may be adjacent to each of the fourth area 10U4 of the upper surface 10U of the enclosure 10.

Referring to FIG. 8, the fourth area 10U4 of the upper surface 10U of the enclosure 10 may be entirely under the first portion 20P1 of the graphite sheet 20, unlike FIGS. 6 and 7B. That is, the first portion 20P1 of the graphite sheet 20 may include an overhang area protruding beyond the first area 10U1 of the upper surface 10U of the enclosure 10.

Referring to FIG. 8, the graphite sheet 20 may include a cutout 20C having a U shape (hereinafter, referred to as a U shape cutout). The graphite sheet 20 having a U shape cutout 20C may include a first portion 20P1, a second portion 20P2, and a third portion 20P3 connecting the first portion 20P1 to the second portion 20P2 with inclination on a first side of the first portion 20P1. Unlike the X-shape cutout 20C, the first portion 20P1 of the graphite sheet 20 is not connected to the second portion 20P2 of the graphite sheet 20 on the other sides of the first portion 20P1.

The cutout area 20C may extend onto the second area 10U2 of the upper surface 10U of the enclosure 10 by a length d1 in a range between about 0.5 mm and about 1 mm. Accordingly, air gaps and graphite sheet wrinkles may be reduced or eliminated while attaching the graphite sheet 20 to the enclosure 10.

An angle θ of inclination of the third area 10U3 of the upper surface 10U of the enclosure 10 may be about 135 degrees or more based on the second area 10U2 of the upper surface 10U of the enclosure 10. Although there is no limitation as to a height, a depth and/or a width of the cutout 20C as long as the cutout 20C extends beyond the first area 10U1 of the upper surface of the enclosure 10, when the angle θ of inclination of the third area 10U3 of the upper surface of the enclosure 10 is steeper than a certain value, delamination of the graphite sheet 20 may occur. The angle θ of inclination may be interchangeably referred to as an approach angle θ.

According to this example embodiments, it may be possible to implement the graphite sheet 20 having a distance or a height difference d2 between the highest point and the lowest point thereof to be about 0.2 mm or more.

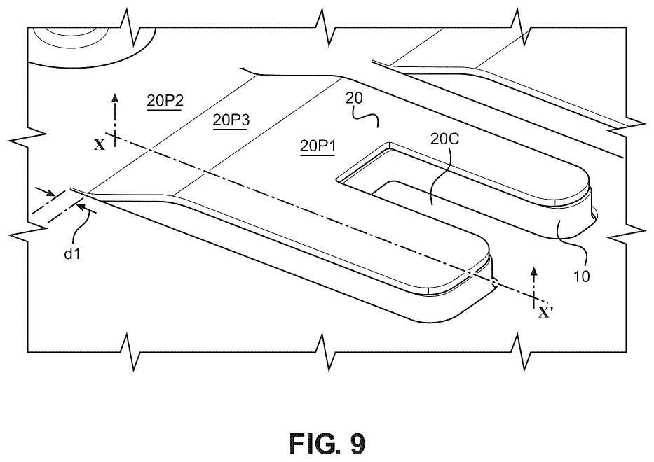

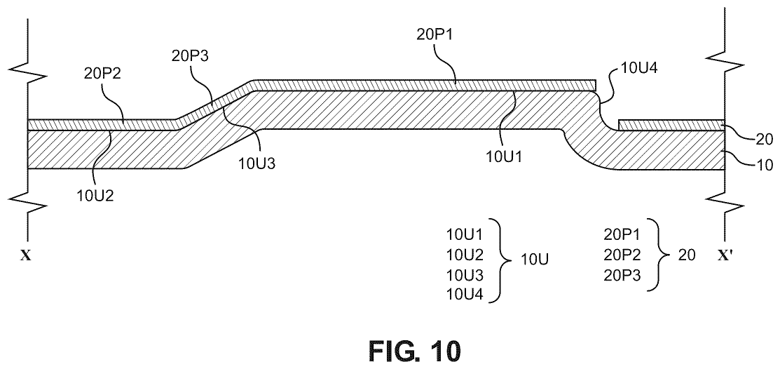

FIG. 9 is an enlarged perspective view of the heat sink structure including an M shape cutout, according to an example embodiment. FIG. 10 is a cross-sectional view of the heat sink structure taken along line X-X′ of FIG. 9. In FIGS. 9 and 10, the same reference numerals as in FIGS. 1-8 denote the same members, respectively. Thus, repeated descriptions thereof are omitted.

Referring to FIG. 9, the first portion 20P1 of the graphite sheet 20 may have a U shape defined by the M shape cutout 20C. The graphite sheet 20 having an M shape cutout 20C may include a first portion 20P1, a second portion 20P2, and a third portion 20P3 connecting the first portion 20P1 to the second portion 20P2 with inclination on a first side of the first portion 20P1. Unlike the X-shape cutout 20C, the first portion 20P1 of the graphite sheet 20 is not connected to the second portion 20P2 of the graphite sheet 20 on the other sides of the first portion 20P1 of the graphite sheet 20, which is different from the first side of the first portion 20P1 of the graphite sheet 20. In other words, the enclosure 10 may be exposed between the first portion 20P1 of the graphite sheet 20 and the first portion 20P2 of the graphite sheet 20 on the other sides of the first portion 20P1, which is different from the first side of the first portion 20P1 of the graphite sheet 20. According to some example embodiments, the first portion 20P1 of the graphite sheet 20 defined by an M shape cutout 20C has a U shape may have a U shape. The two prongs of the U shape of the first portion 20P1 of the graphite sheet 20 may have different width from each other and/or may have different heights from each other.

The cutout area 20C may extend onto the second area 10U2 of the upper surface 10U of the enclosure 10 by a length d1 in a range between about 0.5 mm and about 1 mm. Accordingly, air gaps and graphite sheet wrinkles may be reduced or eliminated while attaching the graphite sheet 20 to the enclosure 10.

Referring to FIG. 9 in conjunction with FIG. 3, the cutout area 20C may extend onto the second area 10U2 of the upper surface 10U of the enclosure 10 by a length d1 in a range between about 0.5 mm and about 1 mm. Accordingly, air gaps and graphite sheet wrinkles may be reduced or eliminated while attaching the graphite sheet 20 to the enclosure 10.

Referring to FIG. 10. the graphite sheet 20 may include a first portion 20P1 on the first area 10U1 of the upper surface 10U of the enclosure 10, a second portion 20P2 on the second area 10U2 of the upper surface 10U of the enclosure 10, and a third portion 20P3 on the third area 10U3 of the upper surface 10U of the enclosure 10 connecting the first portion 20P1 to the second portion 20P2 with inclination.

An angle θ of inclination of the third area 10U3 of the upper surface 10U of the enclosure 10 may be about 135 degrees or more based on the second area 10U2 of the upper surface 10U of the enclosure 10. Although there is no limitation as to a height, a depth and/or a width of the cutout 20C as long as the cutout 20C extends beyond the first area 10U1 of the upper surface of the enclosure 10, as the angle θ of inclination of the third area 10U3 of the upper surface of the enclosure 10 is steeper than a certain value, delamination of the graphite sheet 20 may occur.

According to this example embodiments, it may be possible to implement the graphite sheet 20 having a distance or a height difference d2 between the highest point and the lowest point thereof to be about 0.2 mm or more while avoiding delamination from the enclosure 10 thereunder.

Although not specifically illustrated the present disclosure, depending on example embodiments, the cutout 20C may have a Y shape. The cutout 20C may have various shapes depending on how accessible the heat source (e.g., an electronic component) is for cooling. The X shape cutout may be desirable to spread heat in four directions. However, if there are space limitations, a single U shape cutout may be used to spread the heat in one direction on the graphite sheet 20. The “Y” shape cutout may allow heat to be spread in three directions.

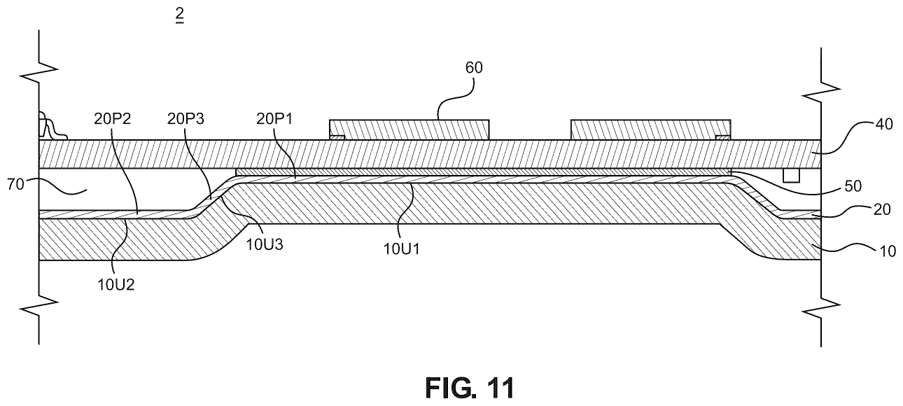

FIG. 11 is a cross-sectional view of a PCBA 2, according to an example embodiment. In FIG. 11, the same reference numerals as in FIGS. 1-10 denote the same members, respectively. Thus, repeated descriptions thereof are omitted.

Referring to FIG. 11, the PCBA 2 may include a heat sink structure 1, a PCB 40 provided on the heat sink structure 1, and a thermal pad 50 interposed between the heat sink structure 1 and the PCB 40, and a potting material 70 filling a space between the PCB 40 and the graphite sheet 20 around the first portion 10U1 of the enclosure 10.

In this example embodiment, the heat sink structure 1 may include an enclosure 10 and a graphite sheet 20, as illustrated in FIG. 4.

The enclosure 10 may have at least one raised area, which corresponds to a potions of at least one heat source 60 (e.g., at least one electronic component) when the enclosure 10 is applied to the PCBA 2 having the at least one heat source mounted thereon. The graphite sheet 20 may conformally cover the at least one raised area of the enclosure 10.

Referring to FIG. 11, an upper surface 10U of the enclosure 10 may include a first area 10U1 at a first height, a second area 10U2 at a second height lower than the first height, and a third area 10U3 connecting the first area to the second area with inclination. The graphite sheet 20 may cover at least the first area 10U1 of the upper surface 10U the enclosure 10.

The graphite sheet 20 may include at least a first portion 20P1 on the first area 10U1 of the upper surface 10U of the enclosure 10, a second portion 20P2 on the second area 10U2 of the upper surface 10U of the enclosure 10, and a third portion 20P3 on the third area 10U3 of the upper surface 10U of the enclosure 10.

Depending on example embodiments, the shape of the cutout 20C of the graphite sheet 20 may vary. For example, the cutout 20C may have an X shape, an M shape, or a U shape as illustrated in FIGS. 1-10.

The at least one heat source 60 may be mounted on the PCB 40. The heat source 60 refers to any electronic component, which produces heat during operation. For example, such an electronic components may include a transistor, a capacitor, an inductor, or a transformer.

To spread heat effectively, each of the one or more graphite sheet patterns may be positioned in alignment with a position of at least one heat source 60 (e.g., at least one electronic component) and may be desired to have a size greater that a size of the at least one heat source 60 (e.g., at least one electronic component).

The thermal pad 50 may be a thermal interface material. The thermal interface material may be a silicone-based material with a relatively good thermal conductivity. In some example embodiments, the thermal pad 50 may include an electrical insulation layer. For example, the thermal pad may include an electrical insulation layer and an elastomer material layer attached thereto. The thermal pad 50 may be placed on (e.g., compressed again) the graphite sheet 20 without an adhesive layer.

The potting material 70 may fill a space between the PCB 40 and the graphite sheet 20 around the first portion 10U1 of the enclosure 10. For example, a liquid potting material may be poured into the PCBA 2 through holes (not specifically illustrated) in the enclosure 10. An empty space between in the PCB 40 and the graphite sheet 20 may be filled with the liquid potting material. Then, the liquid potting material may be solidified into a rubbery material to form the potting material. This potting material 70 may protect the PCBA 2 from shock and vibration, and further help disperse heat away from the electronic components 60 on the PCBA 2 and reduce or prevent “hot spots” from occurring, thereby reducing or preventing damage to the PCBA 2.

Although not specifically illustrated in FIG. 11, the PCBA 2 of FIG. 11 may further includes an adhesive layer 30 between the enclosure 10 and the graphite sheet 20, as illustrated in FIG. 5, to ensure attachment therebetween.

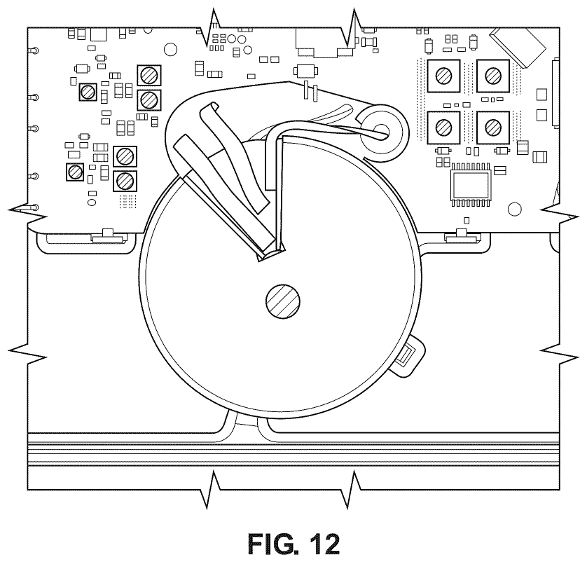

FIG. 12 is a plan view of a front side of a PCBA 2, according to an example embodiment. Shaded shapes in FIG. 12 denote heat sources (e.g., electronic components among the components mounted on the PCB 40).

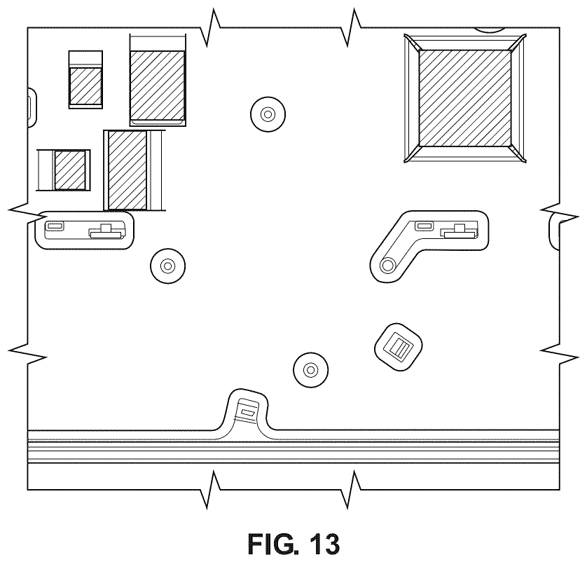

FIG. 13 is a plan view of a rear side of a PCBA 2, according to an example embodiment. Shaded shapes in FIG. 13 denote a raised portion of the graphite sheet corresponding (e.g., in alignment with) the heat sources (e.g., the electronic components) on the front side of the PCBA 2.

Hereinafter, a method of manufacturing the PCBA 2 of FIG. 11 according to an example embodiment will be explained in detail with reference to FIGS. 3-5 and 11.

Referring to FIGS. 4 and 5, an enclosure 10 may be formed to have a raised portion such that an upper surface 10U of the enclosure 10 includes a first area 10U1 at a first height, a second area 10U2 at a second height, and a third area 10U3 connecting the first area 10U1 to the second area 10U2.

Although not specifically illustrated, a graphite sheet may be fed from a roll, placed on a die, and stamped to form a cutout (e.g., X shape, U shape, or M shape) and severed into a graphite sheet 20. The graphite sheet 20 may be pressed against the enclosure 10 thereunder to have a raised portion. Accordingly, as illustrated in FIGS. 3-5, the raised portion of the graphite sheet 20 corresponds to the raised portion of the enclosure 10 and the cutout 20C may include a portion extending onto the second area 10U2 of the upper surface 10U of the enclosure 10 by a length d1 in a range between about 0.5 mm and about 1 mm. In some example embodiments (e.g., FIG. 5), an adhesive layer 30 may be provided between the enclosure 10 and the graphite sheet 20 to facilitate attachment therebetween.

Referring to FIG. 11, a PCB 40, on which heat sources (e.g., electronic components) mounted, may be placed on the graphite sheet 20 with a thermal pad 50 interposed between the graphite sheet 20 and the PCB 40 such that the raised portion of the enclosure 10, the raised portion of the graphite sheet 10 and heat sources (e.g., electronic components) 60 mounted on the PCB 40 are vertically aligned with each other. For example, the thermal pad 50 may be confined on the raised portion of the enclosure 20.

A liquid potting material may be poured through holes (not specifically illustrated) in the enclosure 10 to fill an area between the PCB 40 and the graphite sheet 20 around the first portion 10U1 of the enclosure 10. Thus, an empty space between in the PCB 40 and the graphite sheet 20 may be filled with the liquid potting material. Then, the liquid potting material may be solidified into a rubbery material to form the potting material 70 and thus to provide the PCBA 2 as shown in FIG. 11.

According to some example embodiments, the graphite sheet 20 may include a raised portion on a raised portion (e.g., raised flat portion) of an upper surface of the enclosure 10. The raised portion of the graphite sheet 20 is under and in alignment with a heating element mounted on the PCB, and thus a distance between the graphite sheet 20 and the PCB 40 is reduced, thereby spreading heat more efficiently.

According to some example embodiments, the graphite sheet 20 may be adhered to the enclosure 10 with the cutout 20C to allow the graphite sheet 20 to remain flush or form-fitted to the irregular upper surface 10U of the enclosure 10. Accordingly, air gaps between the enclosure 10 and the graphite sheet 20 may be reduced or prevented, wrinkles in the graphite sheet 20 may be reduced or prevented from occurring, and/or a need for additional heat spreader may be eliminated.

According to some example embodiments of the present disclosure, heat sink structures or PCBAs may be implemented with a reduced number of components (e.g., without a separate heat spreader). In other words, intermediate components such as a thermal grease or a heat spreader (e.g., aluminum heat spreader) may not be needed, while improving heat spreading efficiency. Accordingly, assembly costs and/or assembly time may be reduced.

It should be understood that the example embodiments described herein should be considered in a descriptive sense only and not for purposes of limitation. While some example embodiments have been particularly shown and described, it will be understood by one of ordinary skill in the art that variations in form and detail may be made therein without departing from the spirit and scope of the claims.

What is claimed is:

1. A heat sink structure comprising:
an enclosure having a first horizontal thermal conductivity, the enclosure having an upper surface including
a first area at a first height,
a second area at a second height different from the first height, and
a third area connecting the first area to the second area with inclination; and
a graphite sheet on the enclosure, the graphite sheet having a second horizontal thermal conductivity greater than the first horizontal thermal conductivity of the enclosure, the graphite sheet conformally covering the first area, the third area, and at least a portion of the second area of the enclosure, the graphite sheet including at least one cutout.

2. The heat sink structure of claim 1, wherein the cutout has one of an X shape, an M shape, or a U shape.

3. The heat sink structure of claim 1, wherein the cutout includes
a first cutout area on the first area of the upper surface of the enclosure,
a second cutout area on the second area of the upper surface of the enclosure, and
a third cutout area on the third area of the upper surface of the enclosure, the third cutout area connecting the first cutout area to the second cutout area.

4. The heat sink structure of claim 3, wherein the second cutout area has a length between 0.5 mm and 1 mm in an extension direction of the cutout.

5. The heat sink structure of claim 1, wherein the graphite sheet has an area of at least two times an area of the first area of the enclosure.

6. The heat sink structure of claim 1, wherein an angle of the inclination of the third area of the enclosure is 135 degrees or more based on the second area of the enclosure.

7. The heat sink structure of claim 1, further comprising:
an adhesive layer between the enclosure and the graphite sheet.

8. The heat sink structure of claim 1, wherein the graphite sheet has a height difference of 0.2 mm or more between a lowest point and a highest point thereof.

9. The heat sink structure of claim 1, wherein the enclosure includes a plastic material.

10. The heat sink structure of claim 1, wherein at least one of the first area or the second area of the enclosure is a flat surface.

11. A printed circuit board assembly (PCBA) comprising:
a heat sink structure including an enclosure and a graphite sheet thereon,
the enclosure having a first horizontal thermal conductivity, the enclosure having an upper surface including
a first area at a first height,
a second area at a second height different from the first height,
a third area connecting the first area to the second area with inclination, and
the graphite sheet having a second horizontal thermal conductivity greater than the first horizontal thermal conductivity of the enclosure, the graphite sheet conformally covering the first area, the third area, and at least a portion of the second area of the enclosure, the graphite sheet including at least one cutout;
a printed circuit board (PCB) on the graphite sheet, the PCB configured to mount thereon a heat generating component; and
a thermal pad interposed between the graphite sheet and the PCB.

12. The PCBA of claim 11, wherein the first area of the enclosure is under and in alignment with an area of the PCB, on which the heat generating component is to be mounted.

13. The PCBA of claim 11, wherein the cutout has one of an X shape, an M shape, or a U shape.

14. The PCBA of claim 11, the cutout includes
a first cutout area on the first area of the upper surface of the enclosure,
a second cutout area on the second area of the upper surface of the enclosure, and
a third cutout area on the third area the upper surface of the enclosure, the third cutout area connecting the first cutout area to the second cutout area.

15. The PCBA of claim 14, wherein the second cutout area has a length between 0.5 mm and 1 mm in an extension direction of the cutout.

16. The PCBA of claim 11, wherein an angle of the inclination of the third area of the enclosure is 135 degrees or more based on the second area of the enclosure.

17. The PCBA of claim 11, further comprising:
an adhesive layer between the enclosure and the graphite sheet.

18. The PCBA of claim 11, wherein the thermal pad includes an insulating material layer and an elastomer material layer attached thereto.

19. The PCBA of claim 11, wherein the graphite sheet has a height difference of 0.2 mm or more between a lowest point and a highest point thereof.

20. The PCBA of claim 11, further comprising:
a potting material filling a space between the PCB and the graphite sheet around the first area of the enclosure.
